(19) United States
(12) Patent Application Publication
(10) Pub. No.: US 2010/0007568 A1
(43) Pub. Date: Jan. 14, 2010

(54) Antenna with Balun

(75) Inventors: Elise Fear, Calgary (CA); Michal Okoniewski, Calgary (CA); Mark Andre Campbell, Calgary (CA)

Correspondence Address: FULBRIGHT & JAWORSKI L.L.P., 600 CONGRESS AVE., SUITE 2400, AUSTIN, TX, 78701, US

(73) Assignee: UTI LIMITED PARTNERSHIP, Calgary (CA)

(21) Appl. No.: 12/409,878

(22) Filed: Mar. 24, 2009

Related U.S. Application Data
(60) Provisional application No. 61/039,001, filed on Mar. 24, 2008.

(51) Int. Cl. H03H 5/00; H01Q 13/02; H01Q 1/50

(52) U.S. Cl. 343/772; 333/25; 343/859

(57) ABSTRACT

A balun, generally including a substrate, a microstrip conductor, and a parallel strip conductor is described, where a characteristic impedance of the balun is substantially constant at each cross-sectional point along a length of the balun. A transverse electromagnetic horn antenna can transmit and receive ultra-wide band pulses, and includes a first metal conductor and a second metal conductor, where a characteristic impedance of the first and second conductor varies over a length of the antenna in a controlled means.

### CROSS-REFERENCE TO RELATED APPLICATIONS

This application claims priority to U.S. Provisional Application No. 61/039,001 filed Mar. 24, 2008. The entire text of the above-referenced disclosure is specifically incorporated by reference herein without disclaimer.

### BACKGROUND OF THE INVENTION

1. Field of the Invention

This invention relates to electromagnetic antennas and baluns.

2. Description of Related Art

Various techniques can be used to create images of the human body for clinical purposes or medical science. For example, medical imaging can incorporate radiology, radiological sciences, endoscopy, thermography, medical photography, microscopy, and ultrasonography, to name a few examples. In some embodiments, medical imaging techniques can rely on measuring signal reflections to generate images. For example, in ultrasonography, a probe emits ultrasonic pressure waves and the waves echo inside a medium, such as human tissue. The echo can be measured to produce a reflection signature. The reflection signature can reveal details about the inner structure of the tissue. Microwave imaging for examination of biological tissue has also been proposed. Radar-based microwave imaging involves illumination of the tissue of interest with a short-time pulse. Similar to ultrasonography, reflected microwave pulses can reveal details about the tissue structure. Some microwave imaging systems use an antenna capable of transmitting and receiving ultra-wideband pulses.

### SUMMARY OF THE INVENTION

A balun is described. In select embodiments, the balun includes a substrate, a microstrip conductor; and a parallel strip conductor, where a characteristic impedance of the balun is substantially constant at each cross-sectional point along a length of the balun. In some embodiments, the characteristic impedance is 50Ω. In some embodiments, the balun further includes a variable-width microstrip conductor ground plane. The width of the ground plane and conductor vary along the length of the balun so as to provide the characteristic impedance of the balun that is substantially constant at each cross-sectional point along a length of the balun. In some embodiments, the variable width microstrip conductor ground plane has a contour substantially approximating a 1/x hyperbolic function.

In certain embodiments, the balun further includes an on-board parallel strip to off-board parallel strip transition, wherein the off-board section is parallel to the balun transition. In certain other embodiments, the balun further includes an on-board parallel strip to off-board parallel strip transition where the off-board section is perpendicular to the balun transition. In certain embodiments, said angle further comprises a 45 degree chamfer.

In select implementations, the balun is operable in an immersion medium, such as a low-loss dielectric with permittivity similar to oil, for example, corn, sunflower, canola, soybean, or other patient-friendly oil. Patient friendly oil can include oils that do not adversely affect living tissue, for example, breast tissue.

In another aspect, a balun is described that includes a microstrip input and a parallel strip output. The balun is operable in an immersion medium, and the balun maintains a constant characteristic impedance at each cross-sectional point along its length. In one embodiment, the balun microstrip input has a width of approximately 1.95 mm, and the parallel strip output has a width of approximately 2.60 mm.

In another aspect, an antenna is described. In one embodiment, the antenna includes a first metal conductor, and a second metal conductor, where a characteristic impedance of the first and second conductor varies over a length of the antenna in a controlled manner. In one embodiment, the antenna is a transverse electromagnetic (TEM) horn antenna. The antenna can include a distance between the first and second metal conductors, where the distance is a function of antenna length.

In yet another general aspect, a method for transmitting an ultra-wideband signal into an environment is described. In select embodiments, the method includes transmitting the signal through a balun, wherein the balun output is substantially balanced with respect to current flow, exciting an antenna with the output of the balun and transmitting electromagnetic radiation into the environment.

In yet another general aspect, a method for receiving a signal from an object of interest is described. The method includes receiving electromagnetic radiation at an antenna, wherein the antenna includes a first metal conductor, and a second metal conductor, where a characteristic impedance of the first and second conductor varies over a length of the antenna in a controlled manner. The method further includes transmitting a signal corresponding to the electromagnetic radiation in to a balun. The balun includes a microstrip conductor and a parallel strip conductor, and a characteristic impedance of the balun is substantially constant at each cross-sectional point along a length of the balun. The output of the balun is then received.

Advantages of the balun include, but are not limited to the following. The balun design described herein can provide excellent performance over an ultra-wide frequency range. The performance can generally be attributed to a constant, user-selected characteristic impedance over the length of the balun, which results in minimal signal reflections. In certain select implementations, the constant, characteristic impedance is 50 ohms over the length of the balun. The transverse electromagnetic horn antenna can provide a transition between the impedance of the balun and a second impedance at the aperture of the antenna. Antenna horn plate designs are described that use functions that describe impedance and separation profiles, rather than plate angles. Such an antenna can provide excellent wideband performance, both in terms of minimal reflections at its input and radiated energy pattern.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods, and materials are described below. In addition, the materials, methods, and examples are illustrative only and not intended to be limiting. All publications, patent applications, patents, and other references mentioned herein are incorporated by reference in their entirety. In case of conflict, the present specification, including definitions, will control.

The details of one or more embodiments of the invention are set forth in the accompanying drawings and the description below. Other features, objects, and advantages of the invention will be apparent from the drawings and detailed description, and from the claims.

### BRIEF DESCRIPTION OF THE DRAWINGS

FIG. 1 is a block diagram of a microstrip to parallel strip balun, according to one embodiment.

FIG. 2A shows an example of a ‘SAME’ back-to-back balun structure, according to one embodiment.

FIG. 2B shows an example of a “DIFFERENT” back-to-back balun structure, according to one embodiment.

FIG. 3A shows measured and simulated results for |S₁₁| in back-to-back baluns.

FIG. 3B shows measured and simulated results for |S₂₁| in back-to-back baluns.

FIG. 4 is a block diagram of a parallel plate design transverse electromagnetic (TEM) horn antenna, according to one embodiment.

FIG. 5 is an exemplary TEM horn antenna coordinate system.

FIG. 6 is a one embodiment of a TEM horn antenna and balun apparatus manufactured according to one implementation.

FIG. 7 is a plot of the half energy beam shapes for the TEM horn design shown in FIG. 6.

FIG. 8 shows exemplary locations of near field sensors for the TEM horn antenna design of FIG. 6.

FIG. 9 shows a measured radiation plot obtained at 4 GHz using the TEM horn antenna design shown in FIG. 6.

FIG. 10 is a block diagram of an imaging system, according to one embodiment.

FIG. 11 is a flow diagram of a method for imaging tissue, according to one embodiment.

Like reference symbols in the various drawings indicate like elements.

### DETAILED DESCRIPTION

### Balun Antenna

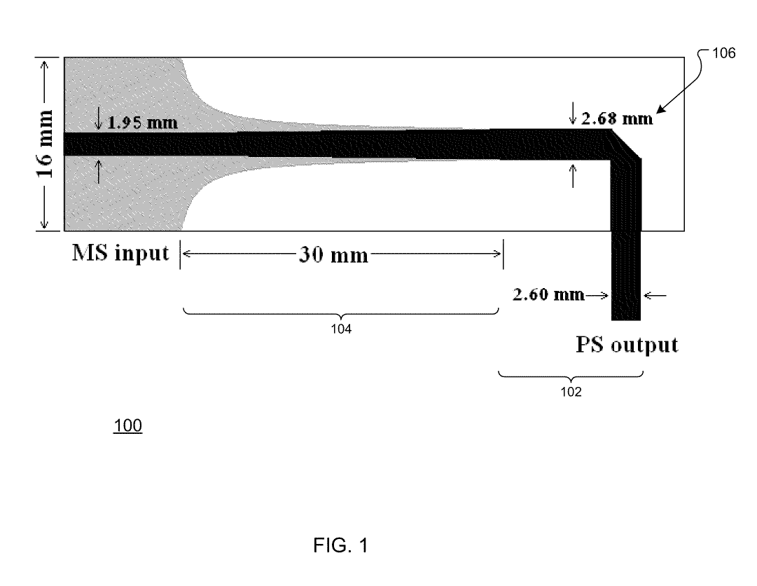

FIG. 1 is one embodiment of a microstrip (MS) to parallel strip (PS) ultra-wideband (UWB) balun 100. The balun 100 can operate with an antenna and can be designed to operate in a lossy dielectric environment, for example, canola oil. The balun design can provide a sufficient scattering parameter obtained from vector network analysis (equivalent to the complex reflection coefficient Γ) and can also provide substantially balanced output currents. In certain embodiments, the balun 100 has a low return loss (|S₁₁|) and a high degree of balance for the output currents. In certain embodiments, the balun 100 includes an on-board parallel strip to off-board parallel strip transition where the off-board section is parallel to the balun transition. In certain other embodiments, the balun 100 includes an on-board parallel strip to off-board parallel strip transition where the off-board section is perpendicular to the balun transition.

In select implementations, the MS to PS balun 100 can be designed to maintain constant characteristic impedance Z₀ of, for example, 50Ω at each cross-sectional point along its length. This design can result in a minimal number of signal reflections as the signal propagates through the balun 100. In addition, the balun 100 can provide a balanced output, thus, creating an accurate radiated energy pattern when connected to an antenna. Since the characteristic impedance is set at a particular value, for example, 50Ω, other balun design constraints can be configured to function around this value. For example, the microstrip line width and ground plane incorporated as part of the balun 100 may be designed to provide 50Ω impedance.

To determine the width of the MS ground plane, the MS can be modeled in a computer modeling program for simulating electromagnetic fields, with Z₀ equal to the selected impedance value. The ground plane width can be initially set very wide (approximately 40 mm) and then reduced gradually until simulations show Z₀ starting to increase above the selected impedance value. The critical width was found to be approximately 16 mm for a selected top conductor width of 1.95 mm, dielectric substrate and environment with relative permittivity of 2.5, and impedance value Z₀ of 50Ω.

In a select implementation, the value of Z₀ is selected to be 50Ω. The width of the PS that can provide a Z₀ of 50Ω in a dielectric of relative permittivity of 2.5 is, as discovered through simulations, 2.68 mm. Based on these results, the top conductor of the MS was set to change linearly between 1.95 and 2.68 mm. To provide a selected Z₀ while the top conductor width changes, an appropriate ground plane width can be determined. In order to accurately construct the ground plane profile for any given length of the transition, the relationship between the top conductor width and the ground plane width can be modeled by fitting data obtained from electromagnetics simulations using a least squares estimation technique. For the dimensions quoted previously, the resulting curve has a 1/x hyperbolic shape, expressed by

Y=0.11729(x−0.958)⁻¹+1.0986, (1)

where Y is the ground plane's half width and x is the top conductor's half width. The curve can be used to produce a desired ground width value over a particular range of top conductor widths.

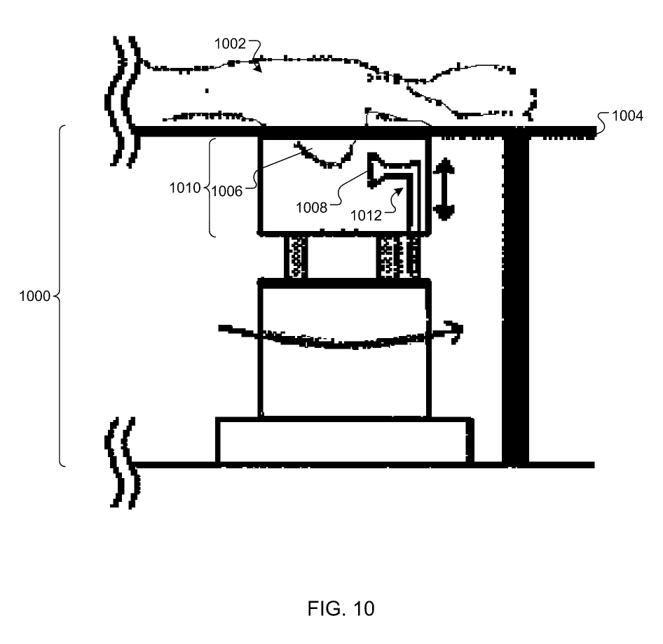

In some embodiments, models of the balun 100 can be constructed and simulations can be performed to determine balun lengths that provide balanced output current and a low return loss (|S₁₁|). For the microstrip and parallel strip examples described previously, a simulation can be performed where balun lengths are selected at 20 mm, 30 mm, and 60 mm. The average |S₁₁| values are −38.6 dB, −40.4 dB and −42.8 dB for the 20 mm, 30 mm, and 60 mm lengths, respectively. The lower conductors have a peak-to-peak current that is 86.8%, 87.4% and 89.1% of the top conductors for the 20 mm, 30 mm and 60 mm lengths respectively. In general, it can be seen that both |S₁₁| and current balance improve with length. As an example, a length of 30 mm was found to be sufficient for the balun 100 operating in system 1000, shown in FIG. 10.

FIG. 1 shows a general balun 100 design combining MS to PS balun 102 with a PS to PS transition 104. The PS to PS transition 102 that extends from the edge of the substrate can be combined with the MS to PS balun 104. The onboard parallel strip line incorporates a 90 degree planar corner 106 with a 45 degree chamfer. This change in direction may provide convenience in locating a feeding cable (e.g., connected to MS input) relative to the TEM horn antenna (e.g., connected to PS output).

In general, balun 100 can be used in a wide variety of electrical engineering applications where signals are transmitted from an unbalanced line to a balanced line. Examples of such applications include, but are not limited to spiral antenna designs.

The output peak-to-peak current balance for the MS to PS balun with PS to PS transition in the above example is 95.1%. It can be seen that there has been a large increase in the degree of balance. The balance may be affected by changes in the geometry after the initial MS to PS transition. A ninety degree planar corner, as shown in FIG. 1, is a common feature in microstrip circuits and is believed to not cause significant reflections in transmitted signals. In certain configurations of a balun 100, the planar corner 106 may help distribute propagating fields and their associated currents more evenly on the parallel strip transmission line.

Baluns 100 can be tested, for example, to measure such variables as |S₁₁| and |S₂₁| (S parameter obtained from e.g. a vector network analyze (VNA)). For example, the balun 100 can be connected to a VNA using coaxial cables; the MS transmission line can be connected using a soldered-on SMA connector. This approach is usually not problematic as the coaxial cable and MS are both unbalanced lines. Difficulty may arise, however, in the inability to connect a coaxial cable to a balanced PS transmission line. In such cases it may be desirable to connect two baluns back-to-back with their PS lines attached to each other, leaving the two SMA connectors available for connection to the VNA. Measured results can then be compared with simulated results of back-to-back baluns.

The output current balance at the PS output can be evaluated, in some cases indirectly. For example, two baluns can be connected together in two different ways and two sets of measurements can be taken. First, the ground planes of both baluns can be connected together electrically. Next, the ground plane of the first balun can be connected to the top conductor of the second balun. These two methods of connecting the baluns together can be referred to as ‘SAME’ and ‘DIFFERENT’.

In some embodiments, the balun includes a substrate. The substrate may be low-loss dielectric with permittivity similar to the surrounding environment or low-loss dielectric with permittivity greater or less than the surrounding environment. In one embodiment, the substrate is RT/duroid 5870 with ∈ᵣ=2.33 and tan δ_{d}=0.0012. The substrate thickness can generally remain constant for the balun; the balun may have different designs with different substrate thicknesses, according to the permittivity and target characteristic impedance. In one embodiment, the substrate is 0.787 mm thick

The substrate width can be of the same width as the MS ground plane. For example, the substrate width can be 16 mm and the copper cladding thickness can be chosen as 17 μm. The MS length before the balun can be variable to allow for connection of any sized SMA connector. In one embodiment the MS length may be 20 mm to allow for connection of the SMA connector.

The spacing between the balun and the 90 degree planar corner may be approximately 10 mm.

In some embodiments, brass shim stock can be used to make the off-board PS conductors. The off-board PS transmission line may be of a desired thickness. In some implementations, the transmission line thickness is approximately 254 um (0.010″).

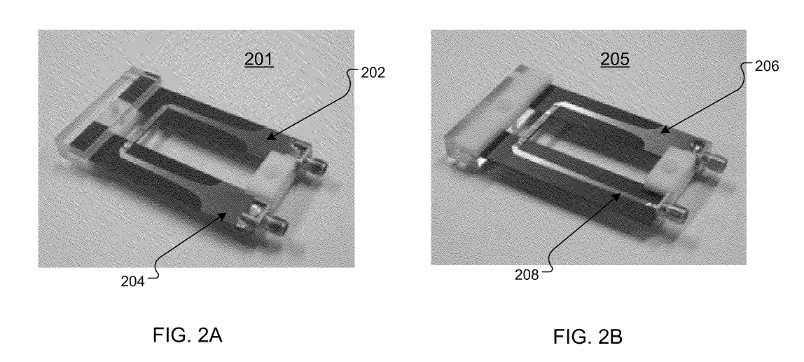

FIG. 2A shows an example of a ‘SAME’ back-to-back balun 201. |S₁₁| and |S₂₁| can be measured and calculated by simulating both the SAME balun 201 and DIFFERENT balun 205 configurations of back-to-back baluns in FDTD software, such as Semcad® (SPEAG, Zurich, Switzerland). Measurements of |S₁₁| and |S₂₁| can be taken using a VNA (e.g., Agilent 8722D, Santa Clara, Calif., U.S.A.).

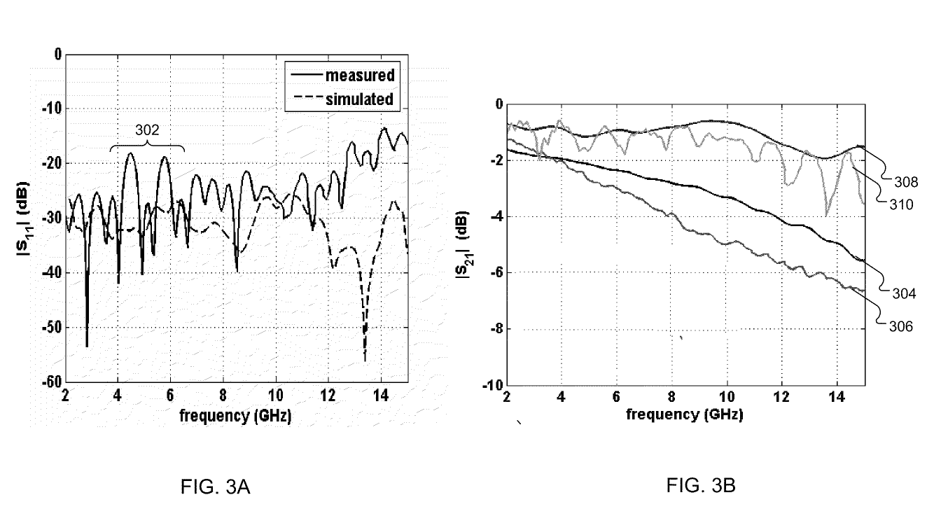

FIG. 3A shows measured and simulated results for |S₁₁| for back-to-back baluns. The results for measured |S₁₁| are shown mostly below −20 dB over the frequency range of 2-12 GHz. Results for |S₁₁| are in good agreement up to 12 GHz with the exception being the large peaks 302 in the measured values at 4.5 and 5.8 GHz. These can be explained by the length of the 21 mm brass conductor and the 16 mm space between the boards. In canola oil, 21 mm is a half-wavelength at 4.5 GHz, and 16 mm is a half-wavelength at 5.9 GHz. Reflections from the beginning and end of these sections can be added together constructively (one wavelength corresponds to the round trip distance) to cause an increase in |S₁₁|.

FIG. 3B shows measured and simulated results for |S₂₁| in back-to-back baluns in both oil and air. In particular, the results for simulation in oil are shown at 304, measured in oil are shown at 306, simulation in air are shown at 308, and results for measured in air are shown at 310. The air results are given to show the strong effect of the lossy oil. The overall trends for the air results are in good agreement, but the measured results exhibit repeated valleys of low |S₂₁|.

In general, the back-to-back baluns in oil show a similar trend between measured and simulated results. Simulations include substrate and oil loss, but the metal is modeled as perfectly conducting, so no loss occurs in it. The loss in the canola oil is frequency dependent. Its conductivity spans a range of values from 0.02 to 0.06 S/m (extrapolated) over the frequency range of 2-15 GHz. The value used for the simulation was 0.032 S/m, which is the value at the single frequency of 6 GHz. Typically, it may not be practical in finite difference time domain (FDTD) simulations to model the metal as a highly conductive dielectric and so the loss due to finite metal conductivity is calculated from theory. This additional loss is then incorporated into the |S₂₁| results shown in FIG. 3B.

In the examples above, it can be seen that both SAME and DIFFERENT configurations give very similar results indicating good output current balance. Because the second balun in the DIFFERENT configuration contains a 90 degree planar corner in the opposite direction when compared to the SAME configuration, some differences in IS₁ could be due to small manufacturing differences.

### TEM Horn Antenna

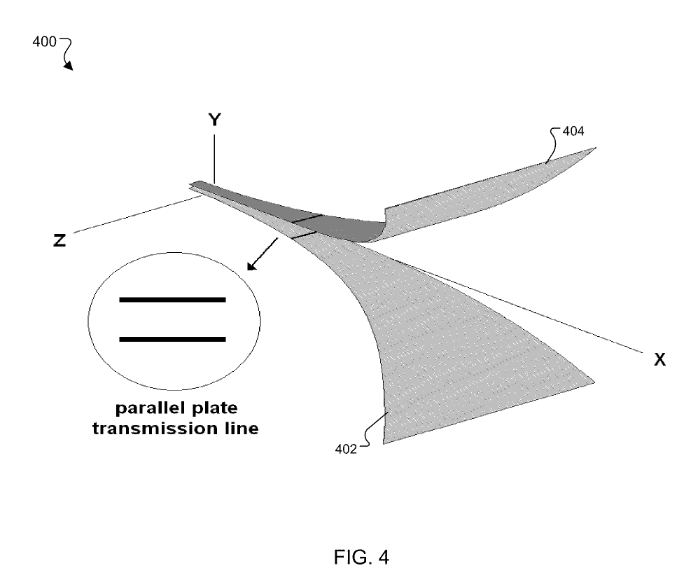

FIG. 4 is a parallel plate transverse electromagnetic (TEM) horn antenna 400, according to one embodiment. The antenna 400 includes a first metal conductor 402 and a second metal conductor 404. Exemplary metal conductors include copper, and brass. The two metal conductors 402 and 404 can be regarded as a parallel plate transmission line at each cross-sectional point along the length of the antenna 400. The characteristic impedance Z₀ of the conductors can vary over the antenna length in a controlled manner. The distance between the metal plates, Y, can be a function of length and can be independent of Z₀.

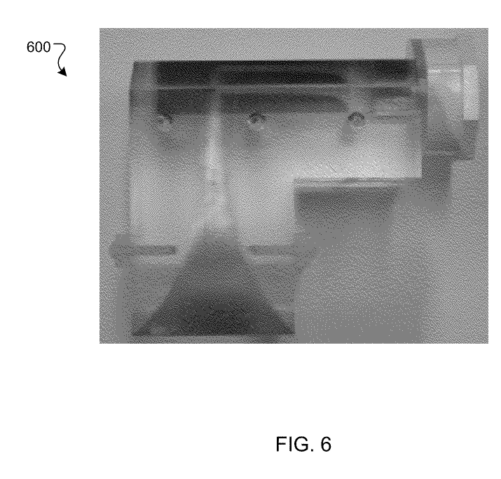

The antenna 400 may be manufactured by machining the metal conductors and bending the conductors into shape using a reference object. For example, a Plexiglas block may be machined into the appropriate shape and the metal conductors fastened to the block with epoxy glue or similar. In another example, shaping and support structures can be composed of polymethyl methacrylate (PMMA). Nylon screws can be used as support structures in some implementations. In some embodiments, the object used to shape the plates may also cover the balun (FIG. 6) and be used to connect the balun and antenna together via pressure rather than solder.

In some embodiments, the thickness of the metal plates can affect the plate characteristic impedance Z₀ slightly when the plates are close together and may affect Z₀ less so when they are far apart. As such, increasing the plate thickness may have the same effect as making it wider, with Z₀ decreasing Z₀ slightly.

In some embodiments, the antenna 400 can be designed to provide a transition between the 50Ω impedance of a balun, such as balun 100 and a second impedance at the aperture of an antenna, for example, antenna 1008 in FIG. 10.

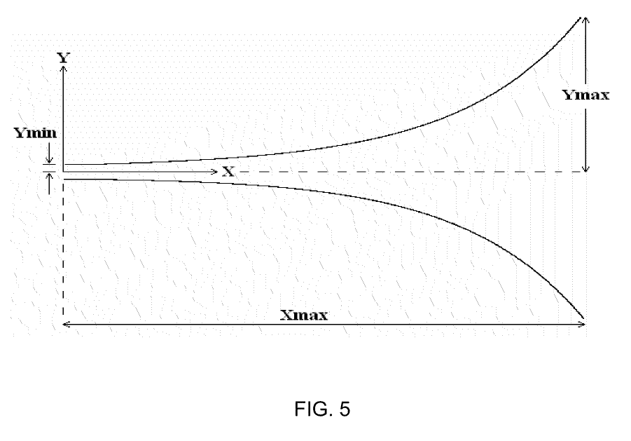

FIG. 5 is an example of a TEM horn antenna coordinate system. In some embodiments, design constraints can be imposed on the measurements within the coordinate system. Typically, Yₘᵢₙ represents half of the plate separation at the feed point and can be constrained by the balun geometry; Wₘᵢₙ represents the width of the metal plates at the feed point and can be constrained by the balun geometry; Z₀ₘᵢₙ represents the characteristic impedance Z₀ of the transmission line formed by the metal plates at the feed point and can be constrained by the balun output impedance; Xₘₐₓ represents the length of the antenna in the boresight direction; Yₘₐₓ represents half the distance between the plates at the aperture of the antenna; Z₀ₘₐₓ represents the characteristic impedance of the metal plates at the aperture of the antenna; Z₀(x) represents the characteristic impedance profile of the metal plates as a function of distance x; and Y(x) represents the separation profile of the metal plates as a function of distance x (taken as the distance from the boresight line to one plate).

The value of Yₘₐₓ, like Xₘₐₓ, may have an effect on the antenna's lower operating frequency, and is generally varied in the examples disclosed herein. In one example, the space constraint for the balun 100 and the space constraint between the antenna and the object to be imaged (e.g., 1-3 cm) implies that Xₘₐₓ can be selected as 8.0 cm. Given particular values of Yₘₐₓ and Z₀ₘₐₓ, there are a large number of ways in which the separation distance and the characteristic impedance can change along the antenna length. Possible profiles for the separation between the plates include linear, circular, and exponential. Possible profiles for the impedance include linear, exponential, circular and near-optimum. Several values of Z₀ₘₐₓ may be tested in order to provide desired antenna performance. In one embodiment, Z₀ₘₐₓ is set to 115Ω.

Z₀ can be calculated for a parallel plate (PP) transmission line. One calculation method includes using an approximation valid under certain plate geometries. Another method includes using an approximation valid under all plate geometries. Both are valid for TEM modes. Both methods can be applied to calculating Z₀ for various PP transmission lines in a surrounding environment with dielectric permittivity different than free space.

In the case where Z₀ is calculated with air as a surrounding medium, the calculation is known in the art and is given as

$$Zo = η \frac{d}{W} = ( \sqrt{\frac{μ}{ɛ}} ) \frac{d}{W} \qquad ( 2 )$$

where the constant η is the intrinsic impedance of the material (usually substrate) between the plates and ∈ and μ are the material's permittivity and permeability respectively. In addition, a conformal mapping technique is generally used to derive several equations for Z₀ based on the ratio W/d and the dielectric constant, k, (relative permittivity ∈ᵣ) of the filling material (usually substrate). Equation (3) can be used for narrow strips (W/d<0.5) and Equation (4) can be used for wider strips (W/d>0.5). Z_{c} is the intrinsic impedance of the surrounding medium.

$$\begin{matrix}{Zo}_{narrow} = {Z}_{c} ( \frac{1}{\sqrt{\frac{k + 1}{2}}} ) ( \frac{1}{π} ) [ \begin{matrix}ln ( \frac{4 d}{W} ) + ( \frac{1}{8} ) {( \frac{W}{d} )}^{2} - \\ ( \frac{1}{2} \cdot \frac{k - 1}{k + 1} ) ( ln \frac{π}{2} + \frac{1}{k} \cdot ln \frac{4}{π} )\end{matrix} ] & ( 3 ) \\ {Zo}_{wide} = \frac{{Z}_{c} \sqrt{\frac{1}{k}}}{\begin{matrix}( \frac{W}{d} ) + 0.441 + \\ \frac{k + 1}{2 π k} [ \begin{matrix}ln ( \frac{W}{d} + 0.94 ) + \\ 1.451\end{matrix} ] + \\ \frac{k - 1}{{k}^{2}} ( 0.082 )\end{matrix}} & ( 4 )\end{matrix}$$

Since the balun and antenna are designed to operate in oil, it may be desirable to know the characteristic impedance of the parallel strip in oil. As such, the following adjustments can be made to equations (3) and (4). The “1” in the “k+1” and “k−1” terms refer to the dielectric constant of air and the term “(k+1)/2” is the average dielectric constant for the filling material and air. To allow for calculations in oil, the dielectric constant of the surrounding medium (air) can be replaced by that of oil. Equations (3) and (4) now become equations (5) and (6) respectively, where the number 1 is replaced with k, corresponding to the dielectric constant of the surrounding medium:

$$\begin{matrix}{Zo}_{narrow} = {Z}_{c} ( \frac{1}{\sqrt{\frac{k + k}{2}}} ) ( \frac{1}{π} ) [ \begin{matrix}ln ( \frac{4 d}{W} ) + ( \frac{1}{8} ) {( \frac{W}{d} )}^{2} - \\ ( \frac{1}{2} \cdot \frac{k - k}{k + k} ) ( ln \frac{π}{2} + \frac{1}{k} \cdot ln \frac{4}{π} )\end{matrix} ] & ( 5 ) \\ {Zo}_{wide} = \frac{{Z}_{c} \sqrt{\frac{1}{k}}}{\begin{matrix}( \frac{W}{d} ) + 0.441 + \\ \frac{k + k}{2 π k} [ \begin{matrix}ln ( \frac{W}{d} + 0.94 ) + \\ 1.451\end{matrix} ] + \\ \frac{k - k}{{k}^{2}} ( 0.082 )\end{matrix}} . & ( 6 )\end{matrix}$$

FIG. 6 is an example of a TEM horn antenna and UWB balun system 600. The system can be implemented in microwave imaging, for example, near-field microwave imaging such as tissue sensing adaptive radar (TSAR), described below. An exemplary TEM horn antenna designed for such purposes may integrate Xₘₐₓ=70 mm, Yₘₐₓ=25 mm, Z₀ₘₐₓ=115Ω, a plate width of 47.8 mm, Z₀(x)=linear and Y(x)=exponential.

The system 600 includes a TEM horn antenna, such as antenna 400 described in FIG. 4, connected to microwave measurement equipment through a balun, such as balun 100 described with respect to FIG. 1. In this particular example, the balun can provide a transition between an unbalanced microstrip line and a balanced parallel strip line. More specifically, the microstrip line can be connected to an SMA connector, which can be connected to a coaxial cable. The coaxial cable can then be connected to a measurement device. The parallel strip line can be attached to the TEM horn antenna.

In general, the system 600 can be immersed, meaning it can be submerged in a selected medium, such as a liquid. In one example, the antenna structure may be fitted inside a volume of canola oil. The antenna can be designed to operate over a frequency range of 2-12 GHz with VSWR<2 or |S₁₁|<−10 dB. The purpose of the antenna may be to transmit only, receive only or transmit and receive a radiated signal. In some cases it may be advantageous to provide a directional radiation pattern with a half energy beam width of 15°-40° at a distance of 2-3 cm from the aperture. Beamwidths within this range provide illumination of a significant portion of the object of interest. The shape of the radiated energy pattern may be circular (cross sectional shape of a single beam) without changing greatly for pulses of different frequency content. In some embodiments, it may be desirable to design an antenna capable of producing near-fields with a fidelity as close to 1 as possible, or between 0.90 and 1.

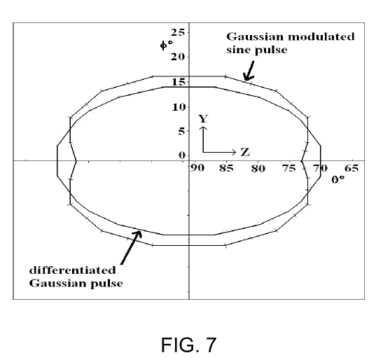

FIG. 7 is a plot of half energy beam shapes for the system 600 shown in FIG. 6. In particular, the half energy beam shapes are shown at 2-3 cm. The half energy beam width is shown at 28 °×40° (Y axis/Z axis) for the differentiated Gaussian pulse and 32°×36° for the Gaussian modulated sine pulse. At a distance of 3 cm, the minimum and maximum fidelity values for the differentiated Gaussian pulse are 0.88 and 0.93, respectively. For the Gaussian modulated sine pulse, the corresponding values were 0.89 and 0.97.

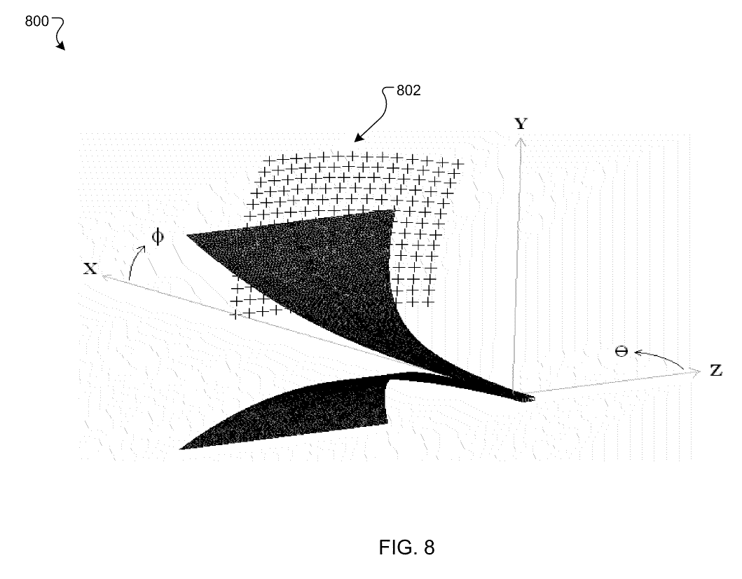

FIG. 8 is an exemplary spherical coordinate system 800 indicating the location of near field sensors in one implementation of the TEM horn antenna design of FIG. 6. The system 800 can be used to inspect the spatial distribution of radiated energy and signal fidelity as a function of location. As shown, the near field sensors 802 are scattered in a plane in the upper right quadrant if one were to look along the antenna's boresight (X axis). The fields are symmetric about both the Y and Z axis. In one example, the range of θ and φ for the sensors can be set to 26° and measurements can be recorded every 2°.

In some embodiments, the sensors 802 are specifically located at three different radii, such that field quantities can be measured at three different distances from the antenna aperture. The radiated pattern of energy emitted from the antenna, which may be pulse specific, can be obtained by determining the relative energy of the radiated pulse passing through points in front of a particular antenna. For example, the relative energy can be calculated by integrating the square of radiated time domain electric field E(t) and repeating the calculation for each location of interest. It is then possible to determine the pattern shape and the half energy beam width. For example, a spherical coordinate system may be used with the magnitude and phase of the electric field recorded on a 2° grid covering the angles of 0°<φ<26° and 64°<θ<90°. For the co-ordinate system defined for the TEM horn antenna, the boresight direction is generally φ=0 and θ=90 (x-axis). Locations at various distances (e.g., 1, 2 and 3 cm) from the antenna aperture can be evaluated.

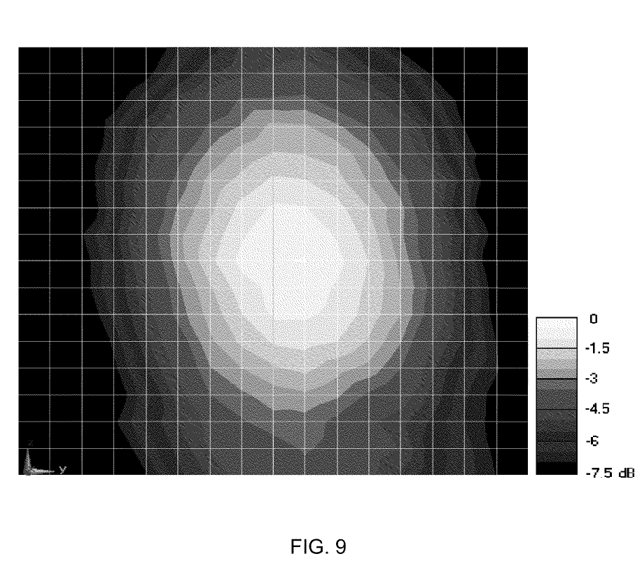

In some embodiments, near field measurements can be taken at several frequencies and compared with simulated near field values at the same frequencies. For example, FIG. 9 shows a measured radiation plot obtained at 4 GHz using the TEM horn antenna design shown in FIG. 6. As shown, the measured pattern (over a planar grid) for the total electric field (|E|) is oval in shape and has substantial symmetry. In particular, the major axis of the oval is parallel with the Z axis of the antenna and the measured half power beam width is approximately 56 mm by 38 mm at a distance of 3 cm. Simulations of the TEM horn antenna can be performed with near field sensors located in a planar array. Results show a half power beam width at 4 GHz to be 60 mm by 40 mm at the same distance, indicating good agreement between measurements and simulations.

The radiated signal fidelity, like the radiated energy pattern, may also be pulse specific and is a measure of similarity between the shapes of two signals or pulses. The fidelity ranges in value from 0 to 1, where 1 indicates that the two signals compared are identical in shape. In the TEM horn antenna example, the radiated pulse is the time derivative of the current flowing on the antenna. Distortion and ringing in the radiated pulse are generally not desirable. When evaluating the radiated pulse fidelity, the same locations as incorporated in determining the energy pattern can be used.

In some implementations, two or more different pulses can be used to evaluate the radiated energy pattern and signal fidelity. For example, the differentiated Gaussian pulse (normally used with TSAR) and the Gaussian modulated sine pulse may be employed. These pulses are given respectively by equations

$$\begin{matrix}v ( t ) = {V}_{o} ( t - {t}_{o} ) exp ( - \frac{{( t - {t}_{o} )}^{2}}{{τ}^{2 }} ) & ( 7 ) \\ v ( t ) = {V}_{O} sin [ 2 π ( {f}_{cen} ) ( t - {t}_{o} ) ] * exp ( - \frac{{( t - {t}_{o} )}^{2}}{2 {σ}^{2 }} ) & ( 8 )\end{matrix}$$

where Vₒ is a scalar, tₒ is the center of the pulse in time, f_{cen} is the center frequency and σ and τ are variables that control the rise time. The variable τ can be set to 62.5e⁻¹² for the first pulse giving a frequency content of just above DC to approximately 12 GHz with a peak around 3.6 GHz. By adjusting the value of σ and f_{cen}, the frequency content of the second pulse can be adjusted on both the lower and the upper sides. The variable σ can be set to 0.9e⁻¹⁰ and f_{cen} set to 6.75 GHz giving frequency content of just above DC to 13.5 GHz.

In some embodiments, radiated pulses can be evaluated using reflections from a strongly scattering object, and from a tumor phantom placed in a breast model, as described below and generally with respect to TSAR. Reflections from a tumor phantom can show that it is possible for clean pulses to be radiated and received with the antenna design.

In some embodiments, measured reflections from the balun and antenna structure can be used to synthesize transmission of pulses through the structure. The resulting signals can be analyzed with the goal of observing any reflections internal to the antenna. In one example, a differentiated Gaussian pulse typical to the TSAR system described below can be used. In another example, a Gaussian modulated sine pulse can be used. In the case of the Gaussian modulated sine pulse, the center frequency can be set to 6.75 GHz and σ can be set to 0.90e-10 s. This gives frequency content between DC and 13.5 GHz. The resulting signals can be plotted and analyzed.

In the TEM horn antenna design of FIG. 6, reflected pulses can be seen from the SMA connector, the balun/antenna connection point, and from the aperture of the antenna. The timing of these reflected pulses may match very closely with the times required to travel the round trip distances from a particular calibration point.

### Balun and Antenna use in Medical Screening

In general, various screening techniques can be implemented to detect disease. Breast cancer screening, for example, can include self and clinical examinations, ultrasound, x-ray mammography, some combination of these techniques, or other techniques. A breast imaging method includes microwave based imaging which relies on the principle that different tissues have different electrical properties and thus reflect electromagnetic energy with different efficiencies. The differences in reflected energy from tissue can be used to provide an image of the structural variations within the tissue, for example. One or more electromagnetic waves can be passed through breast tissue to create an image of significantly scattering objects (high permittivity objects such as tumors) within a specified volume.

TSAR is a microwave imaging system capable of imaging breast tissue. The TSAR method and associated instrumentation used to acquire TSAR signals and images is disclosed in U.S. patent application Ser. No. 10/942,945, filed Sep. 17, 2004, and is fully incorporated herein by reference.

TSAR is a radar-based imaging method that can be used in the early detection of breast cancer. The TSAR modality makes use of short ultra-wideband (UWB) pulses which are radiated by an antenna. TSAR can illuminate the breast using short pulses of microwave energy radiated from an antenna through the breast tissue. The pulses can create reflections that can be received at the same or multiple antenna locations. The received reflections can be analyzed to indicate the location of scattering objects. The locations of the scattering objects can be processed to form an image of the breast.

In one embodiment, a TSAR system can generally include an ultra-wideband (UWB) balun and antenna system capable of transmitting and receiving UWB pulses. The balun and antennas generally described herein can be used in TSAR. In general, a TEM horn antenna, such as that described with respect to FIG. 6, can be used to image a 3D volume such as a human breast. The TEM horn antenna coupled with a UWB balun, such as the balun described with respect to FIG. 1, can be used in the TSAR microwave imaging system to provide an overall radar-based breast tumor detection system.

FIG. 10 is a block diagram of an exemplary TSAR imaging system 1000. The TSAR system 1000 generally relies on differences in electrical properties between various breast tissues. In particular, when pulses of electromagnetic energy pass through breast tissue and encounter a change in the electrical characteristic of the tissue, energy is reflected. By using many pulses from multiple positions around a breast, it is possible to reconstruct an image of the interior of the breast. Images produced using TSAR may show sources of significant backscattered energy within a breast. One advantage provided by the TSAR modality is that, at microwave frequencies, radiated energy is non-ionizing, and therefore provides very little risk of the radiation causing damage to the tissue. As such, there may be no limit on the frequency of screening a patient using TSAR.

As shown in FIG. 10 and during operation of the TSAR imaging system 1000, a subject 1002 lies prone on a table 1004 with the breast 1006 suspended in a coupling medium or simply air. An UWB antenna, such as the antenna described with respect to FIG. 6 above, can be sequentially positioned around the breast 1006 at various locations and heights forming a synthetic array. At each position the breast 1006 is illuminated with a short pulse of microwave energy. In some embodiments, reflected energy can be measured by the same antenna and recorded. Focusing within the 3D volume can be performed synthetically by aligning the signals in time based on path delay.

Typically, the UWB pulses used in TSAR are very short in duration (approximately 0.4 ns) and have significant frequency content spanning 1 GHz up to and including 12 GHz. Therefore, an antenna or antenna system 1010 used in the TSAR system 1000 can be designed to successfully transmit and receive these pulses, and in particular, can be designed to operate over a very large bandwidth (e.g., approximately 2-12 GHz).

In one embodiment, the antenna system includes a TEM horn antenna and a UWB balun as described above. The antenna system can also include antennas based on resistively loaded dipole, tapered slotline or Vivaldi designs.

In operation, the TSAR system 1000 generates pulses synthetically using measurements performed with a vector network analyzer (VNA) or other suitable measurement equipment. A TEM horn antenna is a balanced antenna that is generally attached to the VNA using coaxial cables. However, coaxial cable is an unbalanced transmission line. Therefore, it may be necessary to design a balun structure to connect the unbalanced line to the balanced antenna. The antenna system 1010 includes an antenna and a balun to connect balanced and unbalanced transmission lines during operation of the TSAR system 1000. The balun 100 may additionally be designed to reduce unwanted currents, avoid distorted radiation patterns, and to correct other field effects. The VNA is used to measure reflections from the combined balun and antenna structure. By weighting the frequency-domain measurements with the frequency spectrum of the desired pulse, transmission of a pulse is synthesized.

The antenna 1008 can be designed to transmit and receive UWB pulses. For example, the antenna 1008 may be a TEM horn antenna capable of transmitting and receiving UWB pulses. The TEM horn antenna is a known for its broad band design with many desirable features, such as its directional radiation pattern and adaptability in design. In the example shown, the antenna 1008 is designed with balun 100 and housed within a support structure. The support structure can be designed to fit within a TSAR system 1000, for example.

In some embodiments, the system is operated in a coupling medium or immersion medium to reduce an initial reflection from the skin. The use of the immersion medium reduces the size of the skin reflection which allows more energy to pass into the breast. The immersion medium can include air, oil, or other dielectric that allows more energy to pass into breast tissue. In some embodiments, a particular immersion medium is chosen based on an antenna design. For example, an antenna design may function most efficiently when an immersion medium having a particular dielectric constant is used. In some embodiments in TSAR imaging, an UWB antenna (e.g., 1-12 GHz) configuration may operate efficiently in an immersion medium of canola oil (∈_{R}≈2.5). As such, some of the imaging systems in this disclosure may be designed for immersion in canola oil. In some embodiments, the imaging subject may also employ a different coupling medium to facilitate imaging. Other immersion media are possible and design characteristics may be rescaled, removed, added, or modified in some way to obtain an accurate subject image in a particular medium.

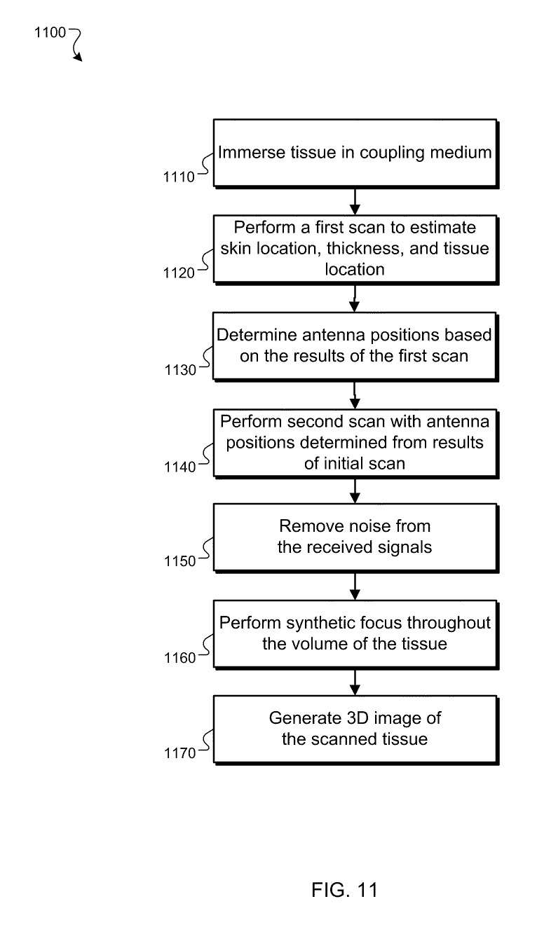

FIG. 11 is a flow diagram of an example method 1100 for imaging tissue in the TSAR imaging system 1000. The method 1100 can be executed on a computer system. In some embodiments the computing system may be coupled to imaging hardware that may include, for example, an energy source that transmits energy into an environment, and an antenna system that can receive backscattered energy from objects within the environment. In some embodiments, the energy source and the antenna system are the same, meaning that one device both transmits energy into the environment and receives backscattered signals from objects within the environment. In other embodiments, the energy source and the antenna system are decoupled. In some embodiments, multiple energy sources and multiple antenna systems can be used to interrogate one environment. In some embodiments, an energy source/antenna system are moved around an environment of interest so as to produce a synthetic array of antennas that captures a region of the environment.

In some embodiments, method 1100 can be performed on breast tissue where the tissue and the antenna placed in a coupling or immersion medium. Selection of an immersion medium can be based on a design constraint of the antenna, the imaging system, or the medium to be imaged. In general, canola oil is known to have a relative permittivity of 2.5-2.3 and a conductivity of 0.02-0.06 S/m over the frequency range of approximately 2-15 GHz. With the high relative permittivity of the skin (approximately 36), there may be a large reflection at the oil/skin interface. The use of the canola oil immersion medium can reduce the size of the skin reflection (compared to air) and thus allow more energy to pass into the breast.

Beginning at step 1110, a tissue is immersed in a selected coupling medium. For example, the breast tissue 1006 can be immersed in canola oil to reduce skin reflections.

Next at step 1120, a first scan of the tissue is performed to estimate a skin location, a tissue thickness, and a tissue location. For example, the scan can include illuminating the breast with short pulses of microwaves. In some embodiments, the TSAR system 1000 can use a differentiated Gaussian pulse to illuminate the breast. The differentiated Gaussian pulse has frequency content that range from just above DC to approximately 12 GHz. As an advantage, this range of frequencies may provide a good compromise between lower frequencies that are able to penetrate farther into the breast and higher frequencies that provide improved spatial resolution.

Next, at step 1130, antenna positions are determined based on the results of the first scan. In a similar fashion, a second scan of the tissue is performed, at step 1140, using the antenna positions determined from the initial scan performed in step 1120. For example, system 1000 can perform operations on signals received during scanning to mitigate noise, or other negative signal effects that may occur during operation of the TSAR system 1000.

At step 1150, clutter and noise is reduced from sent and received signals. At step 1160, synthetic focusing is performed throughout the breast volume. At step 1170, a three dimensional image of the scanned tissue is generated.

It is to be understood that while the invention has been described in conjunction with the detailed description thereof, the foregoing description is intended to illustrate and not limit the scope of the inventive concept, which is defined by the scope of the appended claims. Other aspects, advantages, and modifications are within the scope of the following claims.

What is claimed is:

1. A balun, comprising:
a substrate;
a microstrip conductor; and
a parallel strip conductor;
wherein a characteristic impedance of said balun is substantially constant at each cross-sectional point along a length of said balun.

2. The balun of claim 1, wherein said characteristic impedance is 50Ω.

3. The balun of claim 1, further comprising a variable-width microstrip conductor ground plane, wherein the width of said ground plane varies along a length of the balun so as to provide said characteristic impedance of said balun is substantially constant at each cross-sectional point along a length of said balun.

4. The balun of claim 3, wherein said variable-width microstrip conductor ground plane has a contour substantially approximating a 1/x hyperbolic function.

5. The balun of claim 1, further comprising an on-board parallel strip to off-board parallel strip transition, wherein the off-board section is parallel to the balun transition.

6. The balun of claim 1, further comprising an on-board parallel strip to off-board parallel strip transition where the off-board section is perpendicular to the balun transition.

7. The balun of claim 1, wherein an output of the balun is balanced.

8. The balun of claim 1, wherein said balun is operable in an immersion medium.

9. The balun of claim 8, wherein said immersion medium is oil.

10. The balun of claim 9, wherein said oil is canola oil.

11. The balun of claim 1, wherein said parallel conductor comprises an angle at an on-board portion of said parallel conductor.

12. The balun of claim 11, wherein said angle is approximately 90 degrees; and wherein said angle further comprises a 45 degree chamfer.

13. A balun, comprising:
a microstrip input;
a parallel strip output; and
a microstrip ground plane, in electrical communication with said microstrip input and said parallel strip output;
wherein said balun is operable in an immersion medium; and wherein said balun maintains a constant characteristic impedance at each cross-sectional point along its length.

14. The balun of claim 13, wherein said microstrip input has a width of approximately 1.95 mm, and said parallel strip output has a width of approximately 2.60 mm.

15. An antenna, comprising:
a first metal conductor; and
a second metal conductor;
wherein a characteristic impedance of said first and said second conductor varies over a length of said antenna in a controlled manner.

16. The antenna of claim 15, wherein said antenna is a transverse electromagnetic (TEM) horn antenna.

17. The antenna of claim 15, wherein a distance between said first and said second metal conductors is a function of antenna length.

18. A method for transmitting a balanced signal output, comprising:
receiving electromagnetic radiation at an antenna, wherein said antenna is the antenna according to claim 15;
transmitting a signal corresponding to said electromagnetic radiation into a balun, wherein said balun is the balun according to claim 1; and
receiving a balun output, wherein said balun output is substantially balanced with respect to said signal.
